(19) United States
(12) Patent Application Publication
(10) Pub. No.: US 2025/0022935 A1
(43) Pub. Date: Jan. 16, 2025

(54) SOURCE CONTACT FOR 3D MEMORY WITH CMOS BONDED ARRAY

(71) Applicant: Applied Materials, Inc., Santa Clara, CA (US)

(72) Inventors: Chang Seok Kang, Santa Clara, CA (US); Raghuveer Satya Makala, Campbell, CA (US); Naomi Yoshida, Sunnyvale, CA (US); Hsueh Chung Chen, Cohoes, NY (US); Balasubramanian Pranatharthiharan, San Jose, CA (US)

(73) Assignee: Applied Materials, Inc., Santa Clara, CA (US)

(21) Appl. No.: 18/761,490

(22) Filed: Jul. 2, 2024

Related U.S. Application Data
(60) Provisional application No. 63/526,275, filed on Jul. 12, 2023.

(51) Int. Cl. H01L 29/49; H10B 43/10; H10B 43/27; H10B 43/35

(52) U.S. Cl. CPC H01L 29/4975; H10B 43/10; H10B 43/27; H10B 43/35

(57) ABSTRACT

Methods of manufacturing memory devices are provided. The method comprises forming a first epitaxial layer on a substrate; and forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell.

### CROSS-REFERENCE TO RELATED APPLICATIONS

This application claims priority to U.S. Provisional Application No. 63/526,275, filed Jul. 12, 2023, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide methods for forming back side source contacts for 3D-NAND devices.

### BACKGROUND

Semiconductor technology has advanced at a rapid pace and device dimensions have shrunk with advancing technology to provide faster processing and storage per unit space. Memory devices are widely used to store information including in various electronic devices such as computers, wireless communication devices, cameras, digital displays, and the like.

Wafer bonding technology, such as CMOS bonded array technology, is being introduced to 3D NAND devices in order to improve performance of the device and reduce chip area.

A back side source contact (BSSC) was proposed as a common source line (CSL) contact for CMOS under array (CuA). A substrate polished from the back side of an array wafer to expose channel poly-Si of memory hole and n+ poly-Si is deposited was CSL line. The CSL n+ poly-Si needs to be activated using high temperature (>700° C.). Process temperatures, however, higher than 400° C. cannot be used after wafer bonding since Cu metallization is damaged. Therefore, the incompletely activated n+ poly-Si is connected with TiN/W, and, thus, contact resistance of TiN n+ poly-Si (Rc) and sheet resistance (Rs) of n+Si is an order of magnitude higher than n+ doped epitaxial Si.

Accordingly, there is a need in the art for 3D-NAND devices having high quality lower sheet resistance (Rs) and resistance-capacitance (Rc) along with high aspect ratio contact (HARC) etch stop capability. Additionally, there is a need in the art for methods and apparatus for forming the 3D-NAND devices.

### SUMMARY

One or more embodiments of the disclosure are directed to a method of forming a semiconductor memory device. In one or more embodiments, a method of forming a semiconductor memory device comprises: forming a first epitaxial layer on a substrate; and forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell.

Further embodiments of the disclosure are directed to 3D-NAND memory devices. In one embodiment, a 3D-NAND memory device comprises: a common source line comprising a highly doped epitaxial layer on a substrate; and at least one memory stack formed on the common source line, the at least one memory stack comprising alternating layers of an oxide material and a metal material, at least one memory cell extending from the common source line through the at least one memory stack, and a slit filled with a fill material adjacent to the at least one memory cell, wherein the at least one memory cell includes a semiconductor channel in contact with the highly doped epitaxial layer via a first material.

Still further embodiments of the disclosure are directed to methods of forming a semiconductor memory device. In one or more embodiments, a method of forming a semiconductor memory device comprises: forming a first epitaxial layer on a primary epitaxial layer on a substrate; forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell; bonding the memory array to a peripheral wafer; polishing the substrate to expose the primary epitaxial layer; removing the primary epitaxial layer; etching the first epitaxial layer to form an opening and expose a portion of the memory cell; deposition a first material in the opening; and forming a contact on the filled slit.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a process flow diagram of a method according to one or more embodiments described herein;

FIG. 2A illustrates a cross-sectional view of a device according to one or more embodiments;

FIG. 2B illustrates a cross-sectional view of a device according to one or more alternative embodiments;

FIG. 2C illustrates a cross-sectional view of a device according to one or more alternative embodiments;

FIG. 2D illustrates a cross-sectional view of a device according to one or more alternative embodiments;

FIG. 3 illustrates a cross-sectional view of a device according to one or more embodiments;

FIG. 4 illustrates a cross-sectional view of a device according to one or more embodiments;

FIG. 5 illustrates a cross-sectional view of a device according to one or more embodiments;

FIG. 6A illustrates a cross-sectional view of a device according to one or more embodiments;

FIG. 6B illustrates an enlarged cross-sectional view of region 132 of the device of FIG. 6A according to one of more embodiments;

FIG. 7 illustrates a cross-sectional view of a device according to one or more embodiments;

FIG. 8 illustrates a cross-sectional view of a device according to one or more embodiments;

FIG. 9 illustrates a cross-sectional view of a device according to one or more embodiments;

FIG. 10A illustrates a cross-sectional view of a device according to one or more embodiments;

FIG. 10B illustrates an enlarged cross-sectional view of region 136 of the device of FIG. 10A according to one or more embodiments;

FIG. 11 illustrates a cross-sectional view of a device according to one or more embodiments;

FIG. 12 illustrates a cross-sectional view of a device according to one or more embodiments;

FIG. 13 illustrates a cross-sectional view of a device according to one or more embodiments;

FIG. 14 illustrates a cross-sectional view of a device according to one or more embodiments;

FIG. 15A illustrates a cross-sectional view of a device according to one or more embodiments;

FIG. 15B illustrates an enlarged cross-sectional view of region 148 of the device of FIG. 15A according to one or more embodiments;

FIG. 16A illustrates a cross-sectional view of a device according to one or more embodiments;

FIG. 16B illustrates an enlarged cross-sectional view of region 148 of the device of FIG. 16A according to one or more embodiments;

FIG. 17A illustrates a cross-sectional view of a device according to one or more embodiments;

FIG. 17B illustrates an enlarged cross-sectional view of region 148 of the device of FIG. 17A according to one or more embodiments; and

FIG. 18 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor,” “reactant,” “reactive gas” and the like are used interchangeably to refer to any gaseous species that can react with the substrate surface.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

One or more embodiments provide a processing method in an integrated processing tool to form a common source line comprising a highly doped epitaxial layer, on a substrate and a memory stack formed on the common source line.

In one or more embodiments, common source line (CSL) layers are grown on a blanket silicon substrate in which the common source line has much lower sheet resistance (Rs) and resistance-capacitance (Rc) compared to known common source line layers. In one or more embodiments, the common source line layer comprises a highly doped epitaxial layer that is fully activated with high temperature without any temperature limitations. More specifically, in one or more embodiments, the common source line layer comprises N+ epitaxial silicon that is fully activated with high temperature without any temperature limitations. Advantageously, low sheet resistance (Rs) and low resistance-capacitance (Rc) can be obtained. Additionally, the epitaxial layer on the silicon substrate may function as an etch stop layer for high aspect ratio contact (HARC) etch by adjusting its material properties with additional doping of elements into the layer.

One or more embodiments of the disclosure are described with reference to the Figures. In the method of one or more embodiments, logic or memory devices are fabricated. In specific embodiments, 3-D NAND cell structures are fabricated. In some embodiments, the method forming a first epitaxial layer; and forming a memory array on the first epitaxial layer. The memory array may include a memory stack of alternating layers of an oxide material and a metal material on the first epitaxial layer, at least one memory cell extending from the first epitaxial layer through the memory stack, and a slit filled with a fill material adjacent to the at least one memory cell. In some embodiments, the processing method is performed in a processing tool without breaking vacuum.

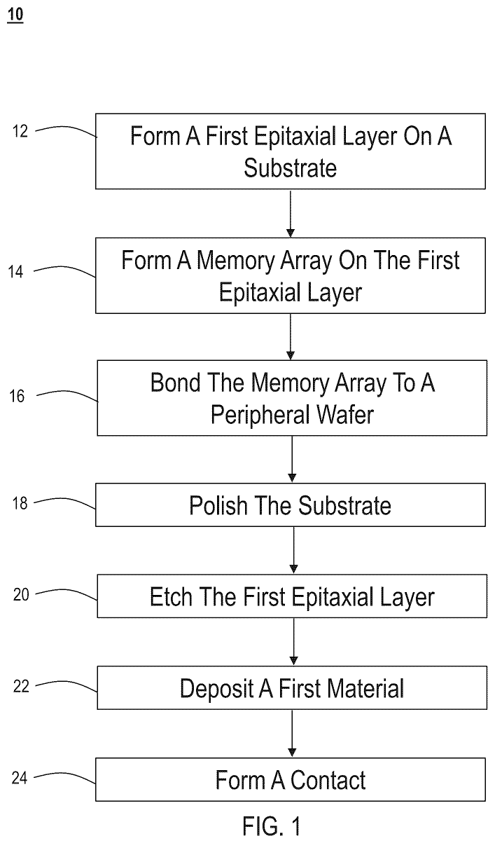

FIG. 1 illustrates a process flow diagram for an exemplary method 10 for forming a memory device. The skilled artisan will recognize that the method 10 can include any or all of the processes illustrated. Additionally, the order of the individual processes can be varied for some portions. The method 10 can start at any of the enumerated processes without deviating from the disclosure. With reference to FIG. 1, at operation 12, a first epitaxial layer is formed on a substrate. In some embodiments, the substrate is first provided prior to formation of the epitaxial layer. As used herein, the term “provided” means that the substrate is made available for processing (e.g., positioned in a processing chamber). At operation 14, a memory array is formed on the first epitaxial layer. At operation 16, the memory array is bonded to a peripheral wafer. At operation 18, the substrate is polished. At operation 20, the first epitaxial layer is etched. At operation 22, the first material is deposited. At operation 24, a contact is formed.

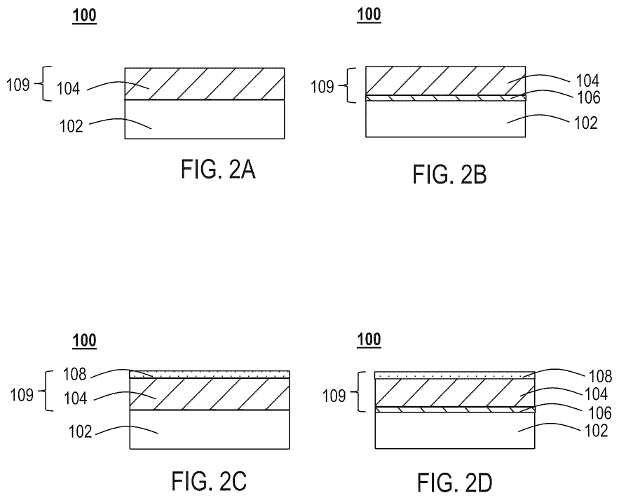

FIGS. 2A-17B illustrate cross-sectional views of a portion of an electronic device 100 following the process flow illustrated for the method 10 in FIG. 1.

With reference to FIG. 1 and FIGS. 2A-2D, at operation 12, a first epitaxial layer 104 is formed on a substrate. FIGS. 2A-2D illustrate an electronic device 100 in accordance with one or more embodiments of the disclosure. In some embodiments, the electronic device 100 shown in FIGS. 2A-2D is formed on the substrate 102, which may be bare, in layers, as illustrated. The electronic device of FIG. 2A is made up of a substrate 102 and a first epitaxial layer 104. The electronic device of FIG. 2B is made up of a substrate 102, a primary epitaxial layer 106, and a first epitaxial layer 104. The electronic device of FIG. 2C is made up of a substrate 102, a first epitaxial layer 104, and a second epitaxial layer 108. The electronic device of FIG. 2D is made up of a substrate 102, a primary epitaxial layer 106, a first epitaxial layer 104, and a second epitaxial layer 108.

The substrate 102 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

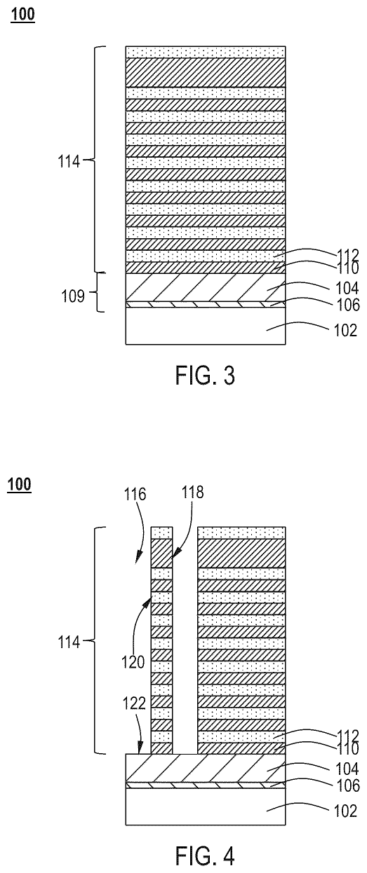

As used herein, the term “epitaxy” refers to a type of crystal growth or material deposition in which new crystalline layers are formed with one or more well-defined orientations with respect to a crystalline seed layer. The deposited crystalline film is called an epitaxial layer. In one or more embodiments, an epitaxial stack 109 comprising one or more epitaxial layer is grown or formed on the substrate 102. In one or more embodiments, epitaxial stack 109 comprises one or more of a first epitaxial layer 104, a primary epitaxial layer 106, and a second epitaxial layer 108. In one or more embodiments, the first epitaxial layer 106, the primary epitaxial layer 106, and the second epitaxial layer 108 are a pre-doped silicon layers. In one or more embodiments, the presence of the primary epitaxial layer 106 and the second epitaxial layer 108 are optional, while the presence of the first epitaxial layer 104 is necessary. Accordingly, while the structure of the epitaxial layers on the substrate 102 may comprise any configuration described in FIGS. 2A to 2D, for ease of drawing, the structure of FIG. 2A is used in subsequent FIGS. 3 through 17B.

In one or more embodiments, the first epitaxial layer 104 may comprise a highly doped epitaxial layer. In one or more embodiments, the highly doped epitaxial layer comprises one or more of N+ silicon doped with one or more of phosphorus (P), arsenic (As), and tin (Sn). In other embodiments, the highly doped epitaxial layer comprises P+ silicon doped with one or more of boron (B), aluminum, gallium (Ga), and carbon (C). In further embodiments, the highly doped epitaxial layer comprises one or more of N+ silicon doped with carbon, N+ silicon doped with germanium, P+ silicon doped with carbon, and P+ silicon doped with germanium.

In one or more embodiments, the first epitaxial layer 104 is N+ silicon doped with one or more of phosphorus (P), arsenic (As), carbon (C), germanium (Ge), or tin (Sn). In other embodiments, the first epitaxial layer 104 is P+ silicon doped with one or more of boron (B), aluminum (Al), gallium (Ga), and carbon (C). The first epitaxial layer 104 may have any suitable thickness. In one or more embodiments, the first epitaxial layer 104 has a thickness in a range of from 20 nm to 500 nm. Without intending to be bound by theory, it is thought that the first epitaxial layer 104 should have a higher removal rate compared to silicon at a specific etching process. The first epitaxial layer 104 may be grown by any suitable process. In one or more embodiments, the first epitaxial layer 104 is grown using a precursor including one or more of DCS, silene, or TCS in an atmosphere of hydrogen (H₂) at a temperature in a range of from 400° C. to 1100° C.

In one or more embodiments, the primary epitaxial layer 106 is P+ silicon doped with boron (B). The primary epitaxial layer 106 may have any suitable thickness. In one or more embodiments, the primary epitaxial layer 106 has a thickness is a range of from 5 nm to 50 nm. Without intending to be bound by theory, it is thought that the primary epitaxial layer 106 should have a higher removal rate compared to silicon at a specific etching process. The primary epitaxial layer 106 may be grown by any suitable process. In one or more embodiments, the primary epitaxial layer 106 is grown using a precursor including one or more of DCS, silene, or TCS in an atmosphere of hydrogen (H₂) at a temperature in a range of from 400° C. to 1100° C. In some embodiments, the primary epitaxial layer 106 has a dopant concentration different than the dopant concentration of the first epitaxial layer 104 (or the highly doped epitaxial layer). In one or more embodiments, the primary epitaxial layer 106 has a dopant type different than the first epitaxial layer 104 (or the highly doped epitaxial layer).

In one or more embodiments, the second epitaxial layer 108 is an epitaxial doped silicon. Without intending to be bound by theory, it is thought that the second epitaxial layer 108 should increase etch stop capability during the subsequent etching of the memory hole. The second epitaxial layer 108 may have any suitable thickness. In one or more embodiments, the second epitaxial layer 108 has a thickness is a range of from 5 nm to 50 nm. The second epitaxial layer 108 may be grown by any suitable process. In one or more embodiments, the second epitaxial layer 108 is grown using a precursor including one or more of DCS, silene, or TCS in an atmosphere of hydrogen (H₂) at a temperature in a range of from 400° C. to 1100° C. In some embodiments, the second epitaxial layer 108 has a dopant concentration different than the dopant concentration of the first epitaxial layer 104 (or the highly doped epitaxial layer). In one or more embodiments, the second epitaxial layer 108 has a dopant type different than the first epitaxial layer 104 (or the highly doped epitaxial layer).

Referring to FIG. 1 and FIGS. 3 through 12, at operation 14, a memory array is formed on the first epitaxial layer 104. With reference to FIG. 3, in one or more embodiments, a stack 114 is formed on the epitaxial stack 109. The stack 114 in the illustrated embodiment comprises a plurality of alternating first material layers 110 and second material layers 112. In one or more embodiments, the first material layers 110 comprise oxide layers and the second material layers 112 comprise nitride layers. The second material layers 112 comprise a material that is etch selective relative to the first material layers 110 so that the second material layers 112 can be removed without substantially affecting the first material layers 110. In one or more embodiments, the second material layers 112 comprises one or more of polysilicon, silicon nitride (SiN), silicon carbide (SiC), silicon oxycarbide (SiOC), germanium (Ge), and titanium nitride (TIN). In one or more embodiments, the second material layers 112 comprise silicon nitride. In one or more embodiments, the first material layers 110 comprise silicon oxide.

The individual alternating layers may be formed to any suitable thickness. In some embodiments, the thickness of each second material layers 112 is approximately equal. In one or more embodiments, each second material layers 112 have a first second layer 112 thickness. In some embodiments, the thickness of each first material layers 110 is approximately equal. As used in this regard, thicknesses which are approximately equal are within +/−5% of each other. In some embodiments, a silicon layer (not shown) is formed between the second material layers 112 and first material layers 110. The thickness of the silicon layer may be relatively thin as compared to the thickness of a layer of second material layers 112 or first material layers 110.

In one or more embodiments, at least one memory hole channel 116 is opened through the stack 114. In some embodiments, opening the memory hole channel 116 comprises etching through the stack 114 to the epitaxial stack 109. Referring to FIG. 4, the memory hole channel 116 has sidewalls that extend through the stack 114 exposing surfaces 120 of the second material layers 112 and surfaces 118 of the first material layers 110. The memory hole channel 116 extends to the epitaxial stack 109 so that the bottom 122 of the memory hole channel 116 is a top surface of the epitaxial stack 109.

In one or more embodiments, the memory hole channel 116 has a high aspect ratio. As used herein, the term “high aspect ratio” refers to a feature having a height: width ratio greater than or equal to about 10, 20, 50, 100, or more.

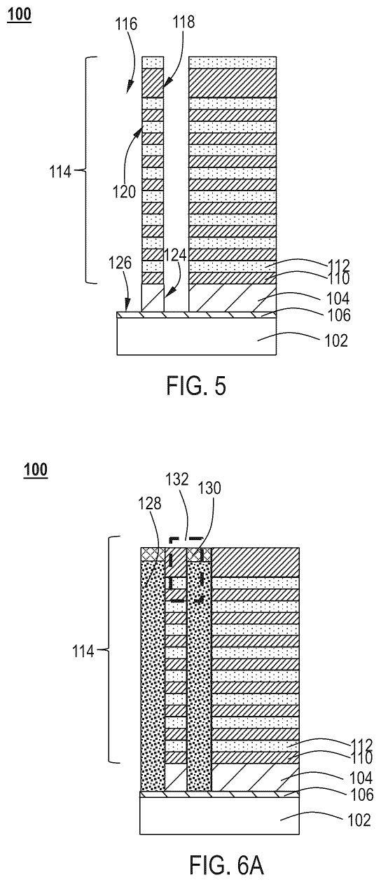

Referring to FIG. 5, the memory hole channel 116 is deepened to etch the first epitaxial layer 104. The first epitaxial layer 104 may be etched by any suitable means. In one or more embodiments, the first epitaxial layer 104 is etched using a plasma etch process including chlorine (Cl₂) and helium (He). In one or more embodiments, etching the epitaxial layer 104 leaves a thin layer of epitaxial layer 104 on the substrate 102. Accordingly, in one or more embodiments, the bottom 126 of the memory hole channel 116 can be formed at any point within the thickness of the first epitaxial layer 104. In some embodiments, the memory hole channel 116 extends a thickness into the first epitaxial layer 104 in the range of from about 10% to about 90%, or in the range of from about 20% to about 80%, or in the range of from about 30% to about 70%, or in the range of from about 40% to about 60% of the thickness of the first epitaxial layer 104. In some embodiments, the memory hole channel 116 extends a distance into the first epitaxial layer 104 by greater than or equal to 10 nm. In some embodiments, the memory hole channel 116 extends from a top surface of the memory stack 114 to a top surface of the substrate 102.

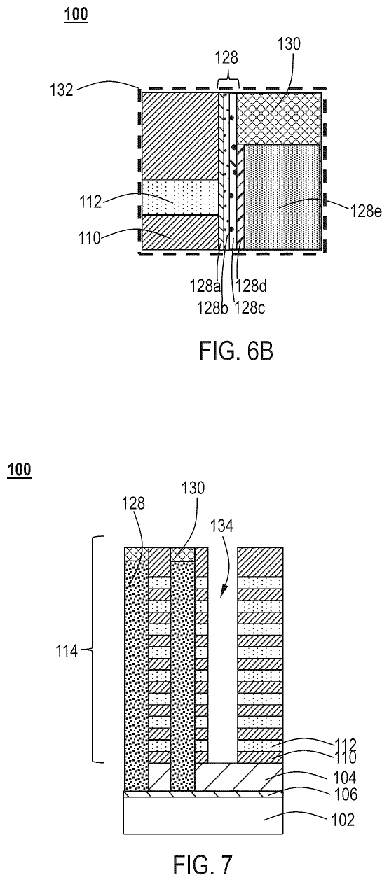

With reference to FIGS. 6A and 6B, the memory cell is formed in the memory hole channel 116. FIG. 6A shows deposition of the transistor layers 128 in the memory hole channel 116. The transistor layers 128 can be formed by any suitable technique known to the skilled artisan. In some embodiments, the transistor layers 128 are formed by a conformal deposition process. In some embodiments, the transistor layers are formed by one or more of atomic layer deposition or chemical vapor deposition.

In one or more embodiments, the deposition of the transistor layers 128 is substantially conformal. As used herein, a layer which is “substantially conformal” refers to a layer where the thickness is about the same throughout (e.g., on the top, middle and bottom of sidewalls and on the bottom of the memory hole channel 114). A layer which is substantially conformal varies in thickness by less than or equal to about 5%, 2%, 1% or 0.5%. The transistor layers 128 in the memory hole may comprise one or more of a blocking layer, a trap layer, a tunnel layer, and a poly-silicon channel.

Referring to FIG. 6B, which is an expanded view of region 132 of FIG. 6A, in one or more embodiments, the transistor layers 128 comprises a blocking oxide layer 128a, a nitride trap layer 128b, a tunnel oxide layer 128c, and a channel material 128d in the memory hole channel 114. In one or more embodiments, the memory hole channel 116 also includes a core oxide layer 128e. In specific embodiments, the core oxide layer 128e comprises silicon oxide (SiOx).

The transistor layers 128 can have any suitable thickness depending on, for example, the dimensions of the memory hole channel 116. In some embodiments, the transistor layers 128 have a thickness in the range of from about 0.5 nm to about 50 nm, or in the range of from about 0.75 nm to about 35 nm, or in the range of from about 1 nm to about 20 nm.

FIGS. 6A-6B illustrate a bit line pad 130 formed on the top surface of the transistor layers 128. While not illustrated, one skilled in the art recognizes that the channel material 128d and the core oxide layer 128e are recessed and an opening is formed that is then filled with a material to form the bit line pad 130. In one or more embodiments, the core oxide layer 128e is recessed an amount in a range of about 100 nm to 250 nm. The bit line pad 130 may comprise any suitable material known to the skilled artisan. In one or more embodiments, the bit line pad 130 comprises polysilicon. In some embodiments, the poly-silicon bit line pad 130 is doped. In other embodiments, the poly-silicon bit line pad 130 is not doped.

Referring to FIG. 7, the device 100 is slit patterned to form a slit pattern opening 134 that extends from a top surface of the stack 114 to the common source line epitaxial stack 109.

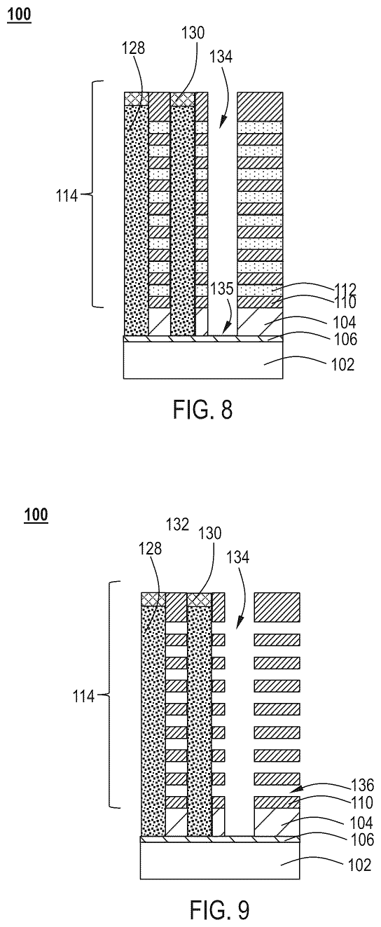

With reference to FIG. 8, the slit pattern opening 134 is deepened to etch the first epitaxial layer 104. The first epitaxial layer 104 may be etched by any suitable means. In one or more embodiments, the first epitaxial layer 104 is etched using a plasma etch process including chlorine (Cl₂) and helium (He). In one or more embodiments, etching the epitaxial layer 104 leaves a thin layer of epitaxial layer 104 on the substrate 102. Accordingly, in one or more embodiments, the bottom 135 of the slit pattern opening 134 can be formed at any point within the thickness of the first epitaxial layer 104 or can be formed within the thickness of the primary epitaxial layer 106 if present. In some embodiments, the slit pattern opening 134 extends a thickness into the first epitaxial layer 104 in the range of from about 10% to about 90%, or in the range of from about 20% to about 80%, or in the range of from about 30% to about 70%, or in the range of from about 40% to about 60% of the thickness of the first epitaxial layer 104. In some embodiments, the slit pattern opening 134 extends a distance into the first epitaxial layer 104 by greater than or equal to 10 nm. In some embodiments, the slit pattern opening 134 extends from a top surface of the memory stack 114 to a top surface of the substrate 102.

FIG. 9 illustrates where the second layers 112 are removed. The second layers 112 may be removed by any suitable means known to the skilled artisan. In one or more embodiments, the second layers 112 are removed by selective etching, e.g., selective wet etching or selective dry etching. Removal of the second layers 112 forms opening 136.

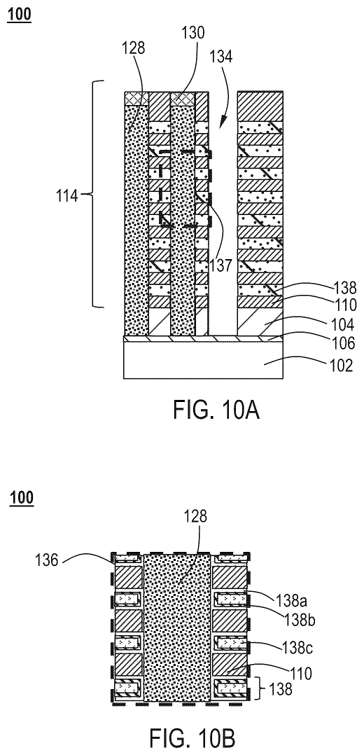

FIGS. 10A and 10B illustrate the formation of the word lines 138. FIG. 10B is an enlarged view of area 137 of FIG. 10A. The word lines 138 comprise one or more of an oxide layer 138a, a barrier layer 138b, and a word line metal 138c. The oxide layer 138a may comprise any suitable material known to the skilled artisan. In one or more embodiments, the oxide layer 138a is an aluminum oxide layer. The barrier layer 138b may comprise any suitable material known to the skilled artisan. In one or more embodiments, the barrier layer 138b comprises one or more of titanium nitride (TiN), tantalum nitride (TaN), or the like. In one or more embodiments, the word line metal 138c comprises a bulk metal comprising one or more of copper (Cu), cobalt (Co), tungsten (W), aluminum (AI), ruthenium (Ru), iridium (Ir), molybdenum (Mo), platinum (Pt), tantalum (Ta), titanium (Ti), or rhodium (Rh). In one or more embodiments, the word line metal 138c comprises tungsten (W). In other embodiments, the word line metal 138c comprises ruthenium (Ru). In one or more embodiments, the word lines 138 comprise one or more of a metal, a metal nitride, a conductive metal compound, and a semiconductor material. The metal may be selected from one or more of tungsten (W), molybdenum (Mo), tantalum (Ta), niobium (Nb), osmium (Os), zirconium (Zr), iridium (Ir), rhenium (Re), or titanium (Ti). The metal nitride may be selected from one or more of titanium nitride (TiN), tantalum nitride (TaN), tungsten nitride (WN), molybdenum nitride (MoN), and zirconium nitride (ZrN). The conductive metal compound may be selected from one or more of tungsten oxide (WOx), ruthenium oxide (RuOx), and iridium oxide (IrOx). The semiconductor material may be selected from one or more of silicon (Si), silicon germanium (SiGe), and germanium (Ge).

FIG. 11 shows where the slit 134 is filled with a liner 140 and a conductor material 142. The liner 140 may comprise any suitable material known to the skilled artisan. In one or more embodiments, the liner 140 comprises silicon oxide (SiOx). The conductor material 142 may be any suitable material known to the skilled artisan. In one or more embodiments, the filled slit comprises a conductor material 142 selected from one or more of N+ silicon, or silicon germanium (SiGe).

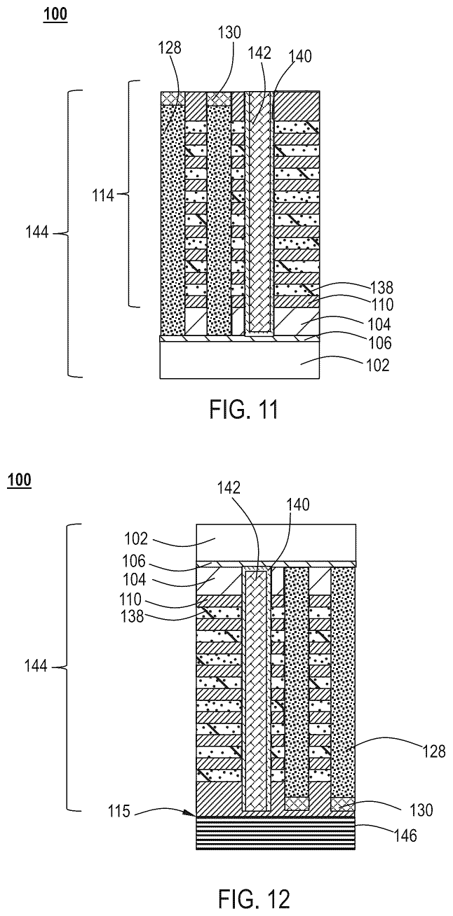

Referring to FIG. 1 and FIG. 12, at operation 16, the memory array 144 is rotated 180 degrees such that the substrate 102 is now on the top of the drawing and the top surface of the memory stack 114 is on the bottom of the drawing. The top surface 115 of the memory stack 114 is bonded to a peripheral wafer 146. The array substrate 102 and the peripheral wafer 146 are boned by Cu—Cu hybrid bonding.

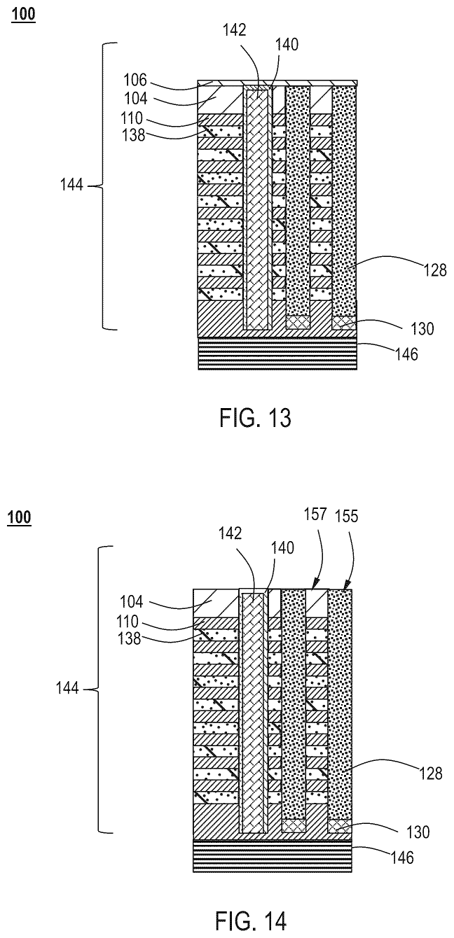

Referring to FIG. 1 and FIG. 13, at operation 18, the substrate 102 is removed or polished. The substrate 102 may be removed by any suitable means known to the skilled artisan. In one or more embodiments, the substrate 102 is removed using one or more of chemical mechanical polishing (CMP) or wet etching.

With reference to FIG. 1 and FIG. 14, at operation 20, the primary epitaxial layer 106, if present, is removed. The primary epitaxial layer 106 may be removed by any suitable means known to the skilled artisan. In one or more embodiments, the primary epitaxial layer 106 is removed by CMP or etch back to expose the bottom 155 of the filled memory hole channel 128 and a portion 157 of the first epitaxial layer 104.

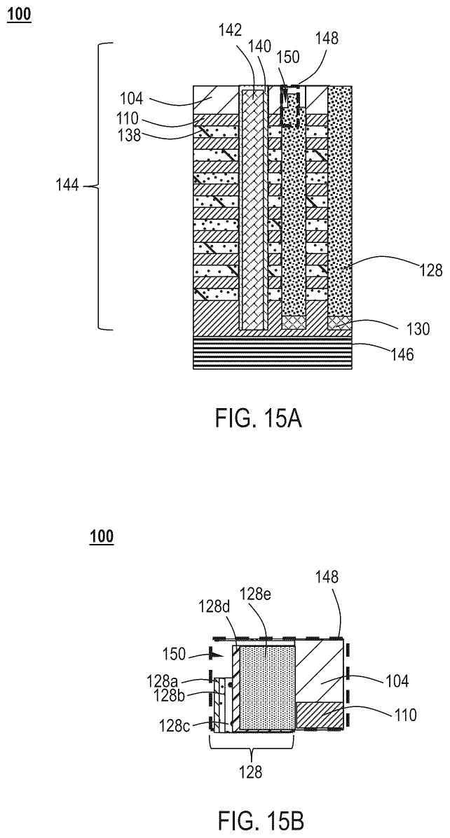

Referring to FIGS. 15A-15B, a portion of the blocking oxide layer 128a, the nitride trap layer 128b, and the tunnel oxide layer 128c present within the epitaxial layer 104 is removed to form an opening 150. The portion of the blocking oxide layer 128a, the nitride trap layer 128b, and the tunnel oxide layer 128c present within the epitaxial layer 104 may be removed by any suitable means known to the skilled artisan. In one or more embodiments, the portion of the blocking oxide layer 128a, the nitride trap layer 128b, and the tunnel oxide layer 128c present within the epitaxial layer 104 is removed by wet etch or selective dry etch to forming the opening 150. Formation of the opening 150 exposes the channel material 128d within the epitaxial layer 104.

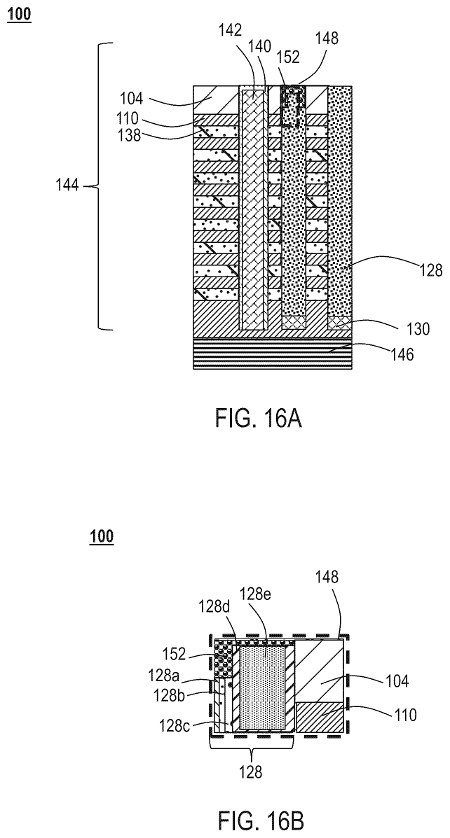

With reference to FIG. 1 and FIGS. 16A to 16B, at operation 22 a first material 152 is deposited in the opening 150. The first material 152 may comprise any suitable material known to the skilled artisan. In one or more embodiments, the first material 152 comprises one or more of silicon (Si), carbon doped silicon (SiC), phosphorus doped silicon (SiPₓ), silicon germanium (SiGe), carbon doped germanium (GeC), carbon doped silicon germanium (SiGeC), and phosphorus doped silicon germanium (SiGePₓ). The first material 152 may be deposited by any suitable means known to the skilled artisan. In one or more embodiments, the first material 152 is deposited by low temperature epitaxial growth or low temperature chemical vapor deposition (CVD).

In other embodiments, the first material 152 comprises a metal silicide. The metal silicide may be any suitable metal silicide known to the skilled artisan. In one or more embodiments, the metal silicide comprises one or more of titanium silicide (TiSi), nickel silicide (NiSi), tungsten silicide (WSi), nickel platinum silicide (NiPtSi), and cobalt silicide (CoSi). The metal silicide may be deposited by any suitable means known to the skilled artisan. In one or more embodiments, the metal silicide is deposited by one or more of physical vapor deposition (PVD) or low temperature chemical vapor deposition (CVD). In other embodiments, the metal silicide is formed by metal deposition followed by silicidation anneal.

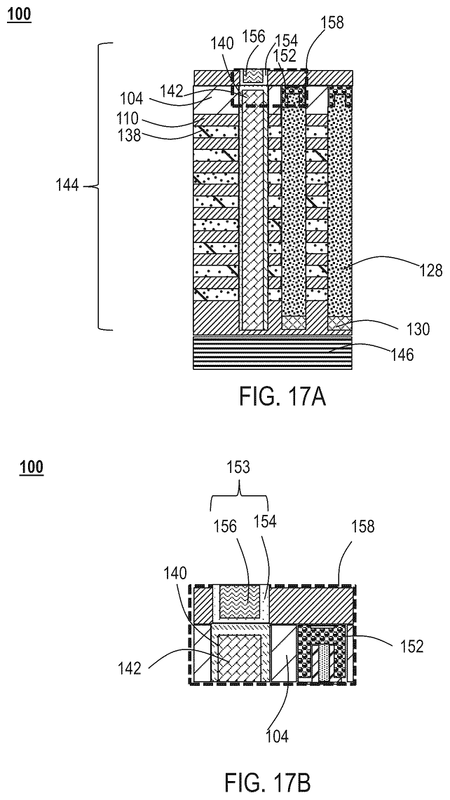

Referring to FIG. 1 and FIGS. 17A to 17B, at operation 24 a contact 153 is formed adjacent on the filled slit pattern 142. The contact 153 includes a contact liner 154 and a contact metal 156. The contact liner 154 may comprise any suitable material known to the skilled artisan. In one or more embodiment, the contact liner 154 comprises one or more of titanium nitride (TiN) and tantalum nitride (TaN). The contact metal 156 may comprise any suitable metal known to the skilled artisan. In one or more embodiments, the contact metal 156 comprises one or more of tungsten (W), copper (Cu), cobalt (Co), aluminum (Al), ruthenium (Ru), iridium (Ir), molybdenum (Mo), platinum (Pt), tantalum (Ta), titanium (Ti), or rhodium (Rh). In one or more embodiments, the contact metal 156 comprises tungsten (W).

One or more embodiments are directed to a method of forming a memory device. In one or more embodiments, the method comprises, consists essentially of, or consists of forming a first epitaxial layer on a substrate; and forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell.

Other embodiments are directed to a method of forming a memory device. In one or more embodiments, the method comprises, consists essentially of, or consists of forming a first epitaxial layer on a primary epitaxial layer on a substrate; forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell; bonding the memory array to a peripheral wafer; polishing the substrate to expose the primary epitaxial layer; removing the primary epitaxial layer; etching the first epitaxial layer to form an opening and expose a portion of the memory cell; depositing a first material in the opening; and forming a contact on the filled slit.

Further embodiments are directed to a memory device, a 3D-NAND memory device more particularly. In one or more embodiments, a 3D-NAND memory device comprises, consists essentially of, or consists of a common source line comprising a highly doped epitaxial layer on a substrate; and at least one memory stack formed on the common source line, the at least one memory stack comprising alternating layers of an oxide material and a metal material, at least one memory cell extending from the common source line through the at least one memory stack, and a slit filled with a fill material adjacent to the at least one memory cell, wherein the at least one memory cell includes a semiconductor channel in contact with the highly doped epitaxial layer via a first material.

The method of one or more embodiments is an integrated method. In one or more embodiments, the method may be performed in one or more processing chamber without breaking vacuum.

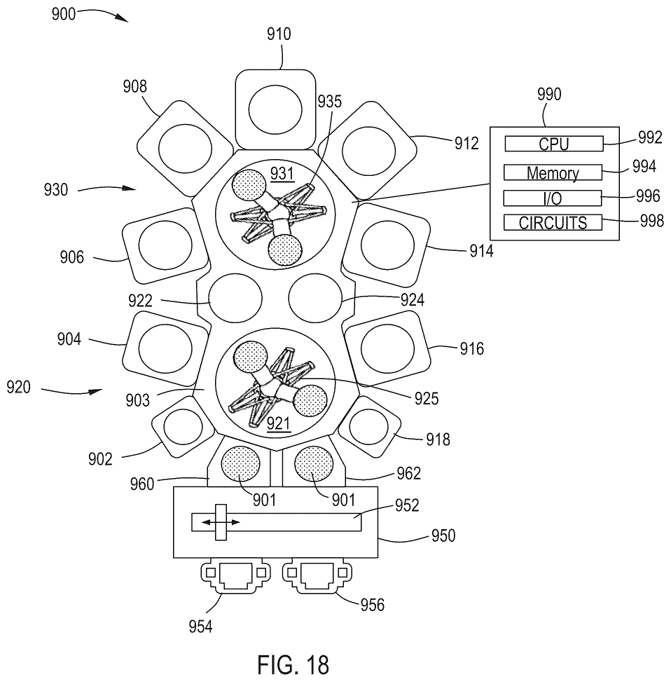

Additional embodiments of the disclosure are directed to processing tools 900 for the formation of the logic or memory devices and methods described, as shown in FIG. 18. The method 10 of one or more embodiments is an integrated method. In one or more embodiments, the method 10 may be performed in one or more processing chamber without breaking vacuum between any of the operations 12, 14, 16, 18, 20, and 22.

In one or more embodiments, the processing tool 900 is a cluster tool that includes at least one central transfer station, e.g., first transfer chamber 921, and second transfer chamber 931, with a plurality of sides. At least one robot 925, 935 is positioned within the at least one central transfer station, e.g., first transfer chamber 921, and second transfer chamber 931, and is configured to move a robot blade and a wafer to each of the plurality of sides.

In one or more embodiments, the processing tool 900 is a cluster tool that comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a deposition (ALD/CVD/PVD) chamber, and an epitaxial growth chamber. The particular arrangement of process chambers and components can be varied depending on the cluster tool and should not be taken as limiting the scope of the disclosure.

In the embodiment shown in FIG. 18, a factory interface 950 is connected to a front of the processing tool 900. The factory interface 950 includes a loading chamber 954 and an unloading chamber 956 on the front of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing tool 900, e.g., a cluster tool. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

In one or more embodiments, the processing tool 900 is a cluster tool that has a first section 920 and a second section 930. The first section 920 is connected to the factory interface 950 through load lock chambers 960, 962. The first section 920 includes a first transfer chamber 921 with at least one robot 925 positioned therein. The at least one robot 925 is also referred to as a robotic wafer transport mechanism. The first transfer chamber 921 is centrally located with respect to the load lock chambers 960, 962, processing chambers 902, 904, 916, 918, and buffer chambers 922, 924. The at least one robot 925 of some embodiments is a multi-arm robot capable of independently moving more than one wafer at a time. In some embodiments, the first transfer chamber 921 comprises more than one robotic wafer transfer mechanism. The at least one robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising one or more of a pre-cleaning chamber, a deposition chamber, and an epitaxial growth chamber; and a controller connected to the central transfer station and the plurality of process stations, the controller configured to activate the robot to move the wafer between process stations, and to control a process occurring in each of the process stations. In one or more embodiments, the controller causes the processing tool to perform the operations of: form a first epitaxial layer on a substrate; and form a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell. In one or more embodiments, the processing tool is maintained under vacuum during each processing operation.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor memory device, the method comprising:
forming a first epitaxial layer on a substrate; and
forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell.

2. The method of claim 1, further comprising forming the first epitaxial layer on a primary epitaxial layer on the substrate.

3. The method of claim 1, further comprising forming a second epitaxial layer between the first epitaxial layer and the memory array prior to forming the memory array.

4. The method of claim 3, further comprising forming the first epitaxial layer on a primary epitaxial layer on the substrate.

5. The method of claim 1, wherein the first epitaxial layer comprises N+ silicon doped with one or more of phosphorus (P), arsenic (As), and tin (Sn).

6. The method of claim 1, wherein the first epitaxial layer comprises P+ silicon doped with one or more of boron (B), aluminum (Al), gallium (Ga), and carbon (C).

7. A 3D-NAND memory device comprising:
a common source line comprising a highly doped epitaxial layer on a substrate; and
at least one memory stack formed on the common source line, the at least one memory stack comprising alternating layers of an oxide material and a metal material, at least one memory cell extending from the common source line through the at least one memory stack, and a slit filled with a fill material adjacent to the at least one memory cell, wherein the at least one memory cell includes a semiconductor channel in contact with the highly doped epitaxial layer via a first material.

8. The memory device of claim 7, wherein the highly doped epitaxial layer is on a primary epitaxial layer on the substrate.

9. The memory device of claim 7, further comprising a second epitaxial layer between the highly doped epitaxial layer and the at least one memory stack.

10. The memory device of claim 9, wherein the highly doped epitaxial layer is on a primary epitaxial layer on the substrate.

11. The memory device of claim 7, wherein the first material comprises one or more of silicon (Si), carbon doped silicon (SiC), phosphorus doped silicon (SiPₓ), silicon germanium (SiGe), carbon doped germanium (GeC), carbon doped silicon germanium (SiGeC), and phosphorus doped silicon germanium (SiGePₓ).

12. The memory device of claim 7, wherein the first material comprises a metal silicide.

13. The memory device of claim 12, wherein the metal silicide comprises one or more of titanium silicide (TiSi), nickel silicide (NiSi), tungsten silicide (WSi), nickel platinum silicide (NiPtSi), and cobalt silicide (CoSi).

14. The memory device of claim 7, wherein the highly doped epitaxial layer comprises N+ silicon doped with one or more of phosphorus (P), arsenic (As), and tin (Sn).

15. The memory device of claim 7, wherein the highly doped epitaxial layer comprises P+ silicon doped with one or more of boron (B), aluminum, gallium (Ga), and carbon (C).

16. The memory device of claim 7, wherein the highly doped epitaxial layer comprises one or more of N+ silicon doped with carbon, N+ silicon doped with germanium, P+ silicon doped with carbon, and P+ silicon doped with germanium.

17. The memory device of claim 8, wherein the primary epitaxial layer has a dopant type different than the highly doped epitaxial layer.

18. The memory device of claim 8, wherein the primary epitaxial layer has a dopant concentration different than a dopant concentration of the highly doped epitaxial layer.

19. The memory device of claim 9, wherein the second epitaxial layer has a dopant type different than the highly doped epitaxial layer.

20. The memory device of claim 9, wherein the second epitaxial layer has a dopant concentration different than a dopant concentration of the highly doped epitaxial layer.

21. A method of forming a semiconductor memory device, the method comprising:
forming a first epitaxial layer on a primary epitaxial layer on a substrate;
forming a memory array on the first epitaxial layer, the memory array comprising a memory stack of alternating layers of an oxide material and a metal material on the first epitaxial layer, at least one memory cell extending from the first epitaxial layer through the memory stack, and a slit filled with a fill material adjacent to the at least one memory cell;
bonding the memory array to a peripheral wafer;
polishing the substrate to expose the primary epitaxial layer;
removing the primary epitaxial layer;
etching the first epitaxial layer to form an opening and expose a portion of the memory cell;
deposition a first material in the opening; and
forming a contact on the filled slit.

22. The method of claim 21, further comprising forming a second epitaxial layer between the first epitaxial layer and the memory array prior to forming the memory array.

23. The method of claim 21, wherein the first epitaxial layer comprises N+ silicon doped with one or more of phosphorus (P), arsenic (As), and tin (Sn).

24. The method of claim 21, wherein the first epitaxial layer comprises P+ silicon doped with one or more of boron (B), aluminum (Al), gallium (Ga), and carbon (C).

25. The method of claim 21, wherein the first material comprises one or more of silicon (Si), carbon doped silicon (SiC), phosphorus doped silicon (SiPₓ), silicon germanium (SiGe), carbon doped germanium (GeC), carbon doped silicon germanium (SiGeC), and phosphorus doped silicon germanium (SiGePₓ).

26. The method of claim 21, wherein the primary epitaxial layer has a dopant concentration different than a dopant concentration of the first epitaxial layer.

27. The method of claim 21, wherein the first material comprises a metal silicide.

28. The method of claim 27, wherein the metal silicide comprises one or more of titanium silicide (TiSi), nickel silicide (NiSi), tungsten silicide (WSi), nickel platinum silicide (NiPtSi), and cobalt silicide (CoSi).
